(19) United States
(12) Patent Application Publication
(10) Pub. No.: US 2016/0365259 A1
(43) Pub. Date: Dec. 15, 2016

(54) SYSTEM FOR WET ETCHING

(71) Applicants: Boe Technology Group Co., Ltd., Beijing (CN); Hefei Xinsheng Optoelectronics Technology Co., Ltd., Anhui (CN)

(72) Inventors: Xiaoning Liu, Beijing (CN); Jaeyun Jung, Beijing (CN); Shikai Wang, Beijing (CN); Dongseob Kim, Beijing (CN); Jun Geng, Beijing (CN); Dengtao Li, Beijing (CN); Xuanqi Liang, Beijing (CN); Tengfei Huang, Beijing (CN)

(21) Appl. No.: 15/131,259

(22) Filed: Apr. 18, 2016

(30) Foreign Application Priority Data
Jun. 11, 2015 (CN) 201510325938.5

(51) Int. Cl. H01L 21/67; H01L 27/12

(52) U.S. Cl. CPC H01L 21/6708; H01L 27/1244; H01L 27/1262

(57) ABSTRACT

A system for wet etching. The system comprises an etching region, a buffer region and a washing region which are communicated in order. An air knife unit is provided at a position at which the buffer region and the clean region connects. The system further comprises a cleaning unit, which is provided correspondingly to the air knife unit, and is used for cleaning the air knife unit. The system efficiently removes the etchant crystal and dust particles attached to the knife edge and periphery of the air knife by means of the cleaning unit. The system can replace the manual cleaning of the air knife, improve operation rate of the device, and reduce waste of labor power as much as possible while ensuring the cleaning effect, while meanwhile avoiding increased particles that would otherwise affect the product yield as a result of lengthy openings of the device cavity.

### CROSS REFERENCE OF RELATED APPLICATION

The present application claims the benefit of Chinese Patent Application No. 201510325938.5, filed by Jun. 11, 2015, the entire disclosure of which is incorporated herein by reference.

### TECHNICAL FIELD

The invention refers to a technical field of display, and specifically to a system for wet etching.

### BACKGROUND

As the TFT-LCD (Thin Film Transistor Liquid Crystal Display) technology matures, the liquid crystal display panel develops rapidly due to its comprehensive performance advantage in the aspects of lightness, contrast, power consumption, lifetime, volume and weight, etc.

In recent years, TFT-LCD has developed towards large dimensions and high resolution. The resistance of the wire is especially important, since it is an important factor causing resistance-capacitance (RC) signal relay. Employing copper in place of the traditional aluminum as the wire has advantages of, for example, low resistance, high film uniformity, and high aperture ratio.

Wet etching etches a portion of the glass substrate which is not covered by the photoresist off with the etchant, so as to form a metal pattern needed. In an actual process, an air knife is mounted at an entrance of a washing unit of a device, for holding back the etchant, and reducing the etchant entering the washing region, to avoid the pollution of the washing unit and increase the service life of the filter. In operation, it is found that the copper wire on the substrate after undergoing the etching process easily generates the problem of wire breaking defects. Thus, an improved technology is needed for overcoming the above defects.

### SUMMARY

During investigation, the present inventor found that the etchant for copper very easily crystallizes, and crystallized particles and dust particles are attached to the knife edge and periphery of the air knife, which easily leads to damage of the substrate in a subsequent process.

In view of the above problems, according to an aspect of the invention, a system for wet etching is proposed, which comprises an etching region, a buffer region and a washing region which are communicated in order; an air knife unit is provided at a position at which the buffer region and the clean region interconnects, wherein the system further comprises a cleaning unit, which is provided correspondingly to the air knife unit, and is used for cleaning the air knife unit.

Optionally, the cleaning unit comprises a nozzle and a washing channel; the washing channel is situated in the buffer region, and connects to the nozzle; the outgoing direction of the nozzle is orientated towards the air knife unit.

Optionally, the washing channel is positioned in the buffer region by a base, which is rotatably connected with the washing channel.

Optionally, there are multiple nozzles, which are provided on the washing channel at intervals.

Optionally, a valve group is provided on the washing channel, which valve group comprises an automatic valve and a manual valve, the manual valve being at a normally open state and the automatic valve connecting to a control unit.

Optionally, the air knife unit comprises a first air knife and a second air knife provided correspondingly from top to down, and a gap for passage of the substrate is provided between the first air knife and the second air knife; the outgoing direction of the nozzle is oriented towards the first air knife.

Optionally, the air knife unit is connected with a gas supply channel, which is connected with a water washing channel in parallel, and a control valve is provided on the water washing channel.

Optionally, the washing region is provided with multiple first sprayers, which are all connected with a water supply pipeline, and the washing channel is connected with the water supply pipeline.

Optionally, the etching region is provided with multiple second sprayers, which are all connected with a solution pipeline.

Optionally, transmission apparatuses for transporting the substrate are provided at the bottom of the buffer region, the etching region and the washing region.

Optionally, the solution pipeline is connected to a source for supplying an etchant for copper.

The above technical solutions of the embodiments of the invention have to the following advantageous effects: by efficiently remove the etchant crystal and dust particles attached to the knife edge and periphery of the air knife by means of the cleaning unit, it is prevented that the photoresist is damaged and the metal layer at this position is etched off due to the crystal and the particles impact the surface of the glass substrate under the action of a high pressure air is flow. The system can replace the manual cleaning to the air knife, improve operation rate of the device, and reduce the waste of labor power as much as possible while ensure the cleaning effect, and meanwhile avoid the particles in the device increasing and affecting the product yield due to open the device cavity for a long time.

### BRIEF DESCRIPTION OF FIGURES

FIG. 1 is a schematic view of a pipeline connection of an existing wet etching device;

FIG. 2 is a schematic view of a positional relation of the cleaning unit and the air knife unit;

FIG. 3 is a schematic view of a system for wet etching;

FIG. 4 is a schematic view of a pipeline connection of a system;

FIG. 5 is a schematic view of a pipeline connection of the air knife unit.

### DETAILED DESCRIPTION

Implementations will be further described in detail below in conjunction with the figures and embodiments. The following embodiments are used for illustration purposes only and not for limiting the scope of the claimed invention.

In order to more clearly illustrate the technical solutions of the embodiments, the provided figures are used throughout the description of the embodiments or the prior art. As should be apparent, the figures in the following description only show some embodiments of the invention. For those common skilled in the art, other embodiments can be obtained according to the figures without applying undue effort. It should be understood that the various parts in the figures may not be drawn to scale. On the contrary, dimensions of some parts may be exaggerated as required.

In the description of the invention, it should be noted that, unless otherwise stated, “multiple” means two or more than two; the orientations or positional relations indicated by the wordings “up”, “down”, “left”, “right”, “inner”, “outer”, “front-end”, “rear-end”, “head”, “tail”, etc. are orientations or positional relations showed based on the figures, and are only used for facilitating and simplifying description of the invention, but not for indicating or implying the apparatus or element has to have a certain orientation and is composed and operated at the certain orientation. Additionally, the wordings “first”, “second”, “third”, etc. are only used for the purpose of description, and cannot be understood as indicating or implying relative importance.

In the following description, it should be noted that, unless otherwise provided with another definition, the wordings “amount”, “connected”, “connecting” should be understood in a broad sense (e.g., may be a fixed connection, or a detachable connection, or an integral connection; may be a mechanical connection or an electrical connection; may be a direct connection, or a indirect connection through an intermediate medium). Those common skilled in the art can understand the specific meaning of the above wordings in the invention according to the specific situation.

The problem in the prior art will be described below referring to FIG. 1. An glass substrate enters the washing region 4 through the buffer region 3 after being etched in the etching region; if etchant crystals and dust particles are attached to the knife edge and periphery of the air knife (the peripheral locations of the first air knife 5 and the second air knife 6). Under the action of the air flow, the crystal particles and dust particles will impact the surface of the glass substrate, resulting in damage of the photoresist, and thus the wires which were covered by the photoresist would be etched during subsequent processes (dry etching, second wet etching), resulting in wire breaking defect.

If for reducing occurrence of the wire breaking defect, a way of sending an engineer to clean regularly the air knife at the entrance of the washing region of the etching device is employed. This results in many problems. First, each cleaning lasts about 30 min per engineer, and in consideration of the to downtime of the device caused by this, each cleaning will last about 60 min, which reduces the operation rate of the device significantly. Second, since the device is relatively wide, the middle location of the device is difficult to clean, the engineer is may have difficulty performing, and the cleaning effect is hard to guarantee. Third, opening the device cavity for a long time will cause dust particles to accumulate in the device and affect the product yield.

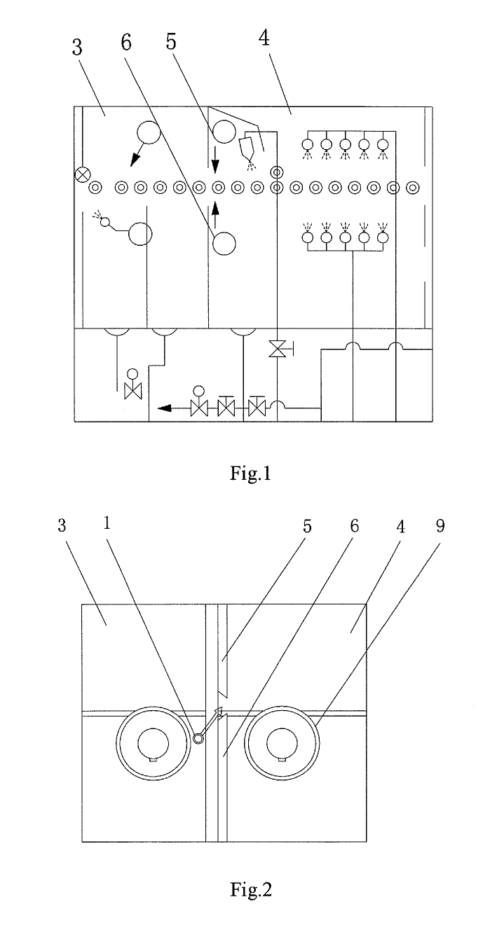

FIGS. 2-4 shows a system for wet etching provided by the embodiment, which comprises an etching region 2, a buffer region 3 and a washing region 4 communicated in order. Transmission apparatuses 9 for transporting the substrate 10 are provided at the bottom of the buffer region 3, the etching region 2, and the washing region 4. The substrate 10 is driven to move by the transmission apparatuses 9, and enters the washing region 4 through the buffer region 3 after being etched in the etching region 2. An air knife unit is provided at the entrance of the washing region 4 (a position at which the buffer region 3 and the clean region 4 interconnects), for holding back the etchant, to reduce the etchant which is brought into the washing region 4 and avoid the washing region 4 from being polluted. Moreover, the system further comprises a cleaning unit 1, which is provided correspondingly to the air knife unit, and is used for cleaning the air knife unit.

The embodiments of the invention mainly aim at the process defect caused by the etchant crystal and dust particles at the knife edge and periphery of the air knife in the existing wet etching device for copper process, and modifies the existing etching device, and efficiently remove the etchant crystal and dust particles attached to the knife edge and periphery of the air knife by the added cleaning unit 1. It should be noted that, the structure and position of the cleaning unit 1 are not limited to those shown in the figures, as long as it meets the requirement of cleaning the air knife unit.

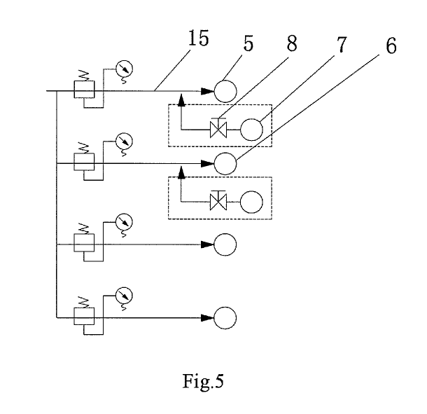

As shown in FIG. 4, the cleaning unit 1 comprises a nozzle 11 and a washing channel 12. The washing channel 12 is situated in the buffer region 3, and connects to the nozzle 11. The washing channel 12 is used for transporting water at a high pressure, to supply the water to the nozzle 11. At the same time, the outgoing direction of the nozzle 11 is orientated towards the air knife unit, to ensure the liquid injected by the nozzle 11 is able to reach the location where the air knife unit is located, so as to realize the effect of washing the air knife unit.

Therein, the number of the nozzle 11 may be set flexibly according to the actual need, and may be one or more. When there are multiple nozzles 11, the multiple nozzles 11 are provided on the washing channel 12 at intervals, and are able to wash multiple air knife units.

Moreover, the washing channel is positioned in the buffer region 3 by a base, which is rotatably connected with the washing channel 12. That is to say, the washing channel 12 can rotate along its circumferential direction (a circumferential direction of the periphery of the washing channel 12) on the base, to facilitate adjusting the injecting angle of the nozzle 11.

Additionally or alternatively, a valve group is provided on the washing channel 12, which valve group comprises an automatic valve 13 and a manual valve 14. Therein, the manual valve 14 is at a normally open state to ensure the clear of the washing channel 12. The automatic valve 13 connects to a control unit, which is used for automatically controlling the open/close of the automatic valve 13. In a special situation, the channel may be closed by the manual valve 14.

When the device is at a nonworking state (i.e. there is no a substrate 10 passing by), under the action of the control unit, the automatic valve 13 of the cleaning unit 1 may be opened automatically, and water at a high pressure may be injected from the nozzle 11 to wash the air knife unit, so that removes the etchant and dust particles attached; when a substrate 10 is etched, the automatic valve 13 is automatically closed, stopping washing. The control of the automatic valve 13 is done by the control unit (for example, implemented by a PLC controller).

In some embodiments, as shown in FIG. 2, the air knife unit comprises: a first air knife 5 and a second air knife 6 provided correspondingly from top to down. That is, the first air knife 5 is situated above, with a downward knife edge; the second air knife 6 is situated below, with a upward knife edge corresponding to the knife edge of the first air knife 5; a gap for passage of the glass substrate is provided between the first air knife 5 and the second air knife 6, so as to hold back the etchant on the substrate 10. Correspondingly, the outgoing direction of the nozzle 11 of the cleaning unit 1 is towards the first air knife 5 (the above air knife), which realizes the following technical effect: after washing the above first air knife 5, the liquid flows down by virtue of gravity, and washes the below second air knife 6 at the same time.

According to another embodiment of the invention, as shown in FIGS. 4 and 5, the first air knife 5 and the second air knife 6 are communicated to a water washing channel 7 respectively. Specifically, the first air knife 5 and the second air knife 6 are connected with a gas supply channel 15 respectively. For cleaning off the dust particles and etchant crystal inside the air knife unit, a water washing channel 7 is added to the gas supply channel 15. The water washing channel 7 can realize the washing inside the air knife unit. Moreover, a control valve 8 is provided on the water washing channel 7.

Certainly, a filter and a manual valve are further provided on the gas supply channel 15. The filter is used for filtering the gas in the gas supply channel 15.

When the air knife unit is to be cleaned periodically, the manual valve on the gas supply channel 15 is closed, and the control valve 8 on the water washing channel 7 is opened, so as to realize cleaning of the inside of the air knife. When the cleaning is finished, the control valve 8 on the water washing channel 7 is closed, and the manual valve on the gas supply channel 15 is opened, and then the interior of the air knife is dried. Combining this cleaning way with the cleaning unit 1 in the above embodiment, the cleaning of the interior and exterior of the air knife unit can be realized.

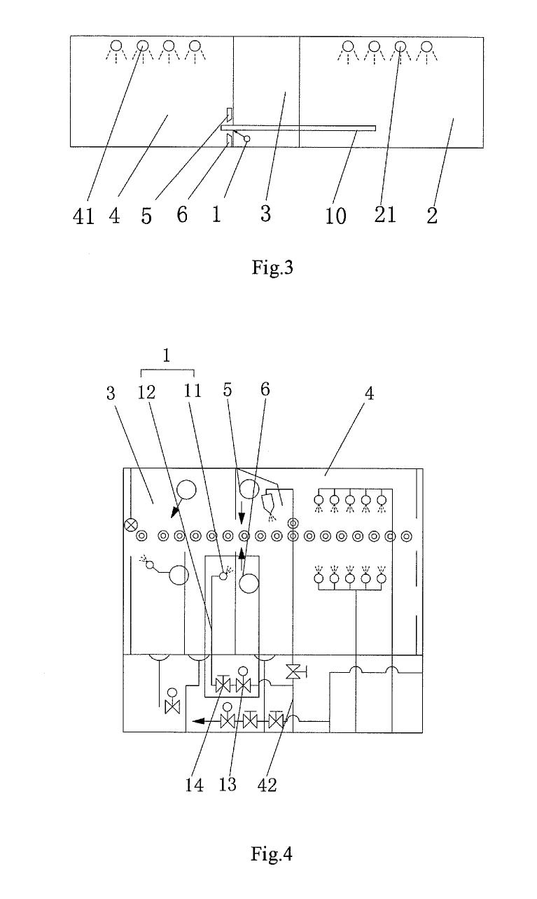

In the present embodiment, the washing region 4 is provided with multiple first sprayers 41 (as shown in FIG. 3), which are all connected with a water supply pipeline 42, and the water washing pipeline 42 is used for supplying water at a high pressure for the first sprayers 41. Certainly, the water supply pipeline 42 connects to a water source. Correspondingly, the washing channel 12 of the cleaning unit 1 is connected with the water supply pipeline 42 in parallel, and can be used as a branch of the water supply pipeline 42. This facilitates modification, which can be done by a small modification based on the existing structure, so as to facilitate popularizing and applying.

Meanwhile, the etching region 2 is provided with multiple second sprayers 42 (as shown in FIG. 3), which are all connected with a solution pipeline, and the solution pipeline is used for supplying etchant for the second sprayers 42.

In general, embodiments disclosed herein provide a system for wet etching, which by efficiently removes the etchant crystal and dust particles attached to the knife edge and periphery of the air knife by means of the cleaning unit, it is prevented that the photoresist is damaged and the metal layer at this position is etched off due to the crystal and the particles impact the surface of the glass substrate under the effect of a high pressure air flow. The system can replace the manual cleaning of the air knife, improve operation rate of the device, and reduce waste of labor power as much as possible while ensuring the cleaning effect, and meanwhile avoid the particle in the device increasing and affecting the product yield due to open the device cavity for a long time.

Embodiments described herein are provided for the purpose of illustration and description, and are not for limiting the claimed invention. Many variations or substitutions may be apparent for those having skill in the art. Choosing and describing the embodiments is for the purpose of better explaining the principle and actual applications, and explanation to those skilled in the art. Therefore, the protection scope of the invention should be only defined by the scope of the claims. It should be noted that the word “comprise” or “comprising” does not exclude presence of elements or steps that are not listed in the claims. The word “a” or “an” preceding an element does not exclude presence of a plurality of such elements. The mere fact that certain measures are recited in mutually different dependent claims does not indicate that a combination of these measures cannot be used to advantage. Any reference signs in the claims should not be construed as limiting the scope.

1. A system for wet etching, comprising:
an etching region, a buffer region, and a washing region, which are communicated in order;
wherein an air knife unit is provided at a position at which the buffer region and the clean region interconnect, and
wherein the system further comprises a cleaning unit provided correspondingly to the air knife unit and used for cleaning the air knife unit.

2. The system for wet etching of claim 1, wherein the cleaning unit comprises a nozzle and a washing channel; wherein the washing channel is situated in the buffer region, and connects to the nozzle; and wherein the outgoing direction of the nozzle is orientated towards the air knife unit.

3. The system for wet etching of claim 2, wherein the washing channel is positioned in the buffer region by a base, which is rotatably connected with the washing channel.

4. The system for wet etching of claim 2, further comprising multiple nozzles provided on the washing channel at intervals.

5. The system for wet etching of claim 2, wherein a valve group is provided on the washing channel, wherein the valve group comprises an automatic valve and a manual valve, the manual valve being at a normally open state and the automatic valve connecting to a control unit.

6. The system for wet etching of claim 2, wherein the air knife unit comprises a first air knife and a second air knife arranged correspondingly from top to down, wherein a gap for passage of the substrate is provided between the first air knife and the second air knife; and wherein the outgoing direction of the nozzle is oriented towards the first air knife.

7. The system for wet etching of claim 1, wherein the air knife unit is connected with a gas supply channel connected with a water washing channel in parallel, and wherein a control valve is provided on the water washing channel.

8. The system for wet etching of claim 2, wherein the air knife unit is connected with a gas supply channel connected with a water washing channel in parallel, and wherein a control valve is provided on the water washing channel.

9. The system for wet etching of claim 3, wherein the air knife unit is connected with a gas supply channel connected with a water washing channel in parallel, and wherein a control valve is provided on the water washing channel.

10. The system for wet etching of claim 4, wherein the air knife unit is connected with a gas supply channel connected with a water washing channel in parallel, and wherein a control valve is provided on the water washing channel.

11. The system for wet etching of claim 5, wherein the air knife unit is connected with a gas supply channel connected with a water washing channel in parallel, and wherein a control valve is provided on the water washing channel.

12. The system for wet etching of claim 6, wherein the air knife unit is connected with a gas supply channel connected with a water washing channel in parallel, and wherein a control valve is provided on the water washing channel.

13. The system for wet etching of claim 2, wherein the washing region is provided with multiple first sprayers connected with a water supply pipeline, and wherein the washing channel is connected with the water supply pipeline.

14. The system for wet etching of claim 1, wherein the etching region is provided with multiple second sprayers connected with a solution pipeline.

15. The system for wet etching of claim 1, wherein transmission apparatuses for transporting the substrate are provided at the bottom of the buffer region, the etching region, and the washing region.

16. The system for wet etching of claim 14, wherein the solution pipeline is connected to a source for supplying an etchant for copper.
